(19) United States
(12) Patent Application Publication
(10) Pub. No.: US 2008/0157252 A1
(43) Pub. Date: Jul. 3, 2008

(54) Optical sensor package

(75) Inventors: Chia-Chu Cheng, Yonghe City (TW); Tzu-Heng Liu, Lujhou City (TW); Wei-Chih Hsu, Jhonghe City (TW); Kun-Hsun Lee, Taipei City (TW)

Correspondence Address: RABIN & Berdo, PC, 1101 14TH STREET, NW, SUITE 500, WASHINGTON, DC, 20005, US

(73) Assignee: LITE-ON SEMICONDUCTOR CORP., Taipei Hsien (TW)

(21) Appl. No.: 12/000,487

(22) Filed: Dec. 13, 2007

(30) Foreign Application Priority Data
Dec. 27, 2006 (TW) 095222961

(51) Int. Cl. H01L 31/00

(52) U.S. Cl. 257/434; 257/E31.054

(57) ABSTRACT

The invention provides an optical sensor package. The package comprises a circuit board, an image sensor module and a packaging cap. The image sensor module electrically connects to the circuit board; the packaging cap is mounted on the circuit board and integrally packages the image sensor module. Hereby, the new architecture of the invention is not complex and its volume is small. The cost of the package is low, and the invention has the functions of electrostatic discharge and waterproofing; besides, the packaging cap can integrally package the image sensor module and a light-emitting module.

### BACKGROUND OF THE INVENTION

1. Field of the Invention

The present invention is related to a circuit board package, especially a package for an optical sensor.

2. Description of Related Art

Please refer to FIG. 1 and FIG. 2, illustrating a traditional optical sensor package for collecting fingerprints. The traditional optical sensor package comprises a circuit board 1a, an image sensor module 2a, a light-emitting module 3a, a packaging cap 4a, and two transparent caps 5a.

The image sensor module 2a and the light-emitting module 3a are disposed on the circuit board 1a and electrically connected to it. The image sensor module 2a comprises one or more complementary metal-oxide semiconductor (CMOS) image sensor chips, the light-emitting module 3a comprises one or more light-emitting devices 30a. The image sensor module 2a uses wire-bonding technology to electrically connect to the circuit board 1a via conductive wires 6a. The light-emitting module 3a uses wire-bonding technology to electrically connect to the circuit board 1a via conductive wires 6a′. The packaging cap 4a is mounted on circuit board 1a. The packaging cap 4a has one first opening 40a and one second opening 41a. The first opening 40a is corresponding to the image sensor module 2a, and the second opening 41a is corresponding to the light-emitting device 30a of the light-emitting module 3a.

Besides, a pair of first holes 12a is mounted on the circuit board 1a, the packaging cap 4a has a pair of second holes 42a which is corresponding to first holes 12a. Users put the packaging cap 4 on the circuit board 1a in the correct position by matching the first holes 12a with the second holes 42a. The two transparent caps 5a are used for protecting conductive wires 6a.

The disadvantage of this design is that the packaging cap 4a must have the first opening 40a and the second opening 41a, and the image sensor module 2a and the light-emitting module 3a can protrude out of the first opening 40a and the second opening 41a respectively. If users want to put the packaging cap 4 on the correct position of the circuit board 1a, they must match the first holes 12a with the second holes 42a. Besides, the architecture and the manufacture process of the traditional optical sensor package are complex, and the costs of assembling and manufacturing the package are high.

The inventors of the present invention believe that the shortcomings above can be remedied and suggest the present invention, which is of reasonable design, and is an effective improvement based on deep research and theory.

### SUMMARY OF THE INVENTION

The object of the present invention is to provide an optical sensor package that uses a packaging cap to integrally package an image sensor module mounted on a circuit board. The architecture of the package is simple, the volume of the package is small, and the costs for manufacturing and assembling the package are low.

For achieving the object described above, the present invention provides an optical sensor package, comprising:

a first circuit board;
an image sensor module mounted on the first circuit board, connecting electrically to the first circuit board; and
a packaging cap mounted on the first circuit board, packaging the image sensor module.

Besides, a light emitting module can be mounted on the circuit board and connected to it electrically. The packaging cap packages the light-emitting module integrally.

### BRIEF DESCRIPTION OF THE DRAWINGS

FIG. 1 is an exploded perspective view of a traditional package of an optical module for collecting fingerprints.

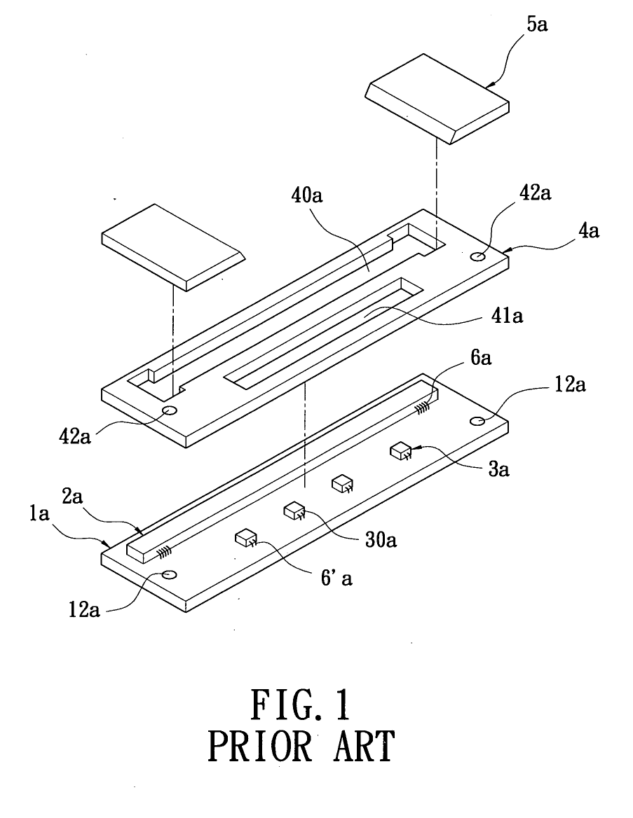

FIG. 2 is a perspective view of the assembled optical module of FIG. 1.

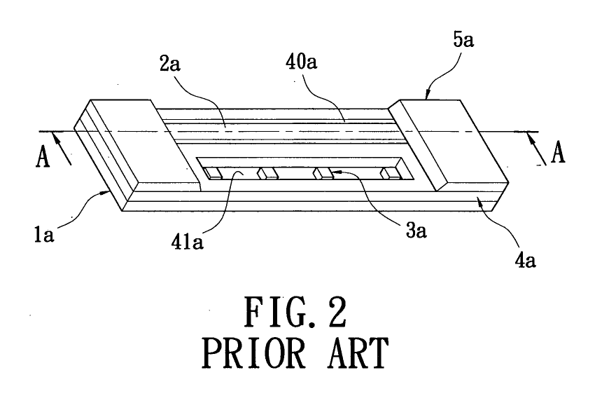

FIG. 3 is a cross-sectional view along the line A-A in FIG. 2.

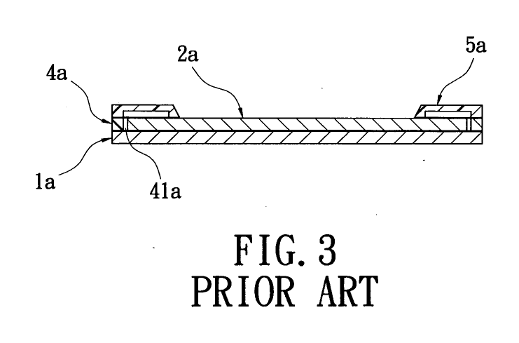

FIG. 4 is an exploded perspective view of the first embodiment of the optical sensor package of the present invention.

FIG. 4A is an exploded perspective view of the second embodiment of the optical sensor package of the present invention.

FIG. 4B is an exploded perspective view of the third embodiment of the optical sensor package of the present invention.

FIG. 5 is an assembled perspective view of the first embodiment of the optical sensor package of the present invention.

FIG. 6 is a cross-sectional view along the line A-A in FIG. 5.

FIG. 7 is a cross-sectional view along the line B-B in FIG. 5.

FIG. 8 is a cross-sectional view of the optical sensor package of the present invention electrically connecting to another circuit board.

FIG. 9 is an exploded view of the forth embodiment of the optical sensor package of the present invention.

FIG. 9A is an exploded view of the fifth embodiment of the optical sensor package of the present invention.

### DETAILED DESCRIPTION OF THE PREFERRED EMBODIMENTS

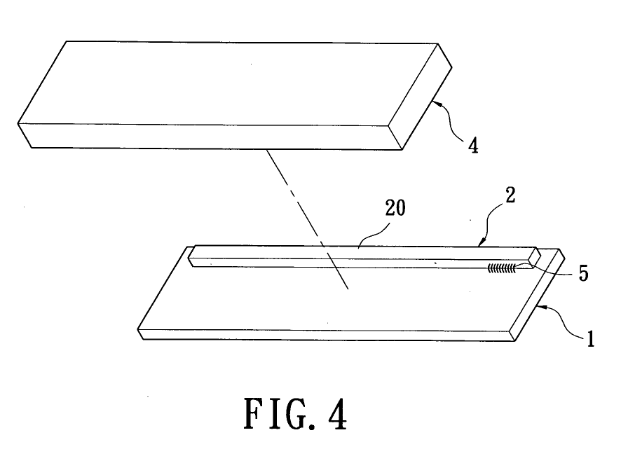

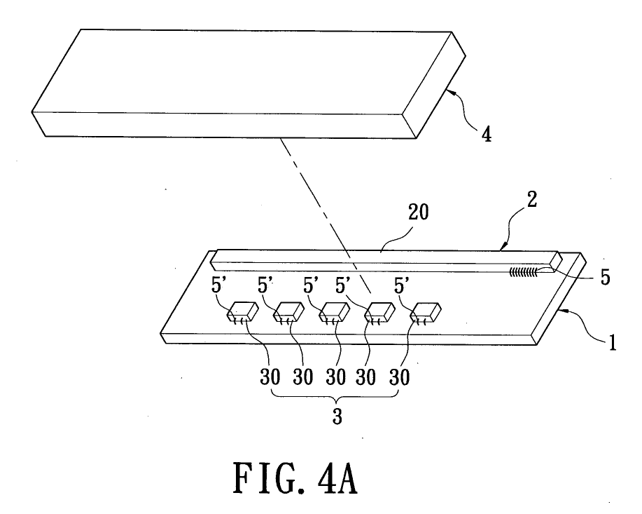

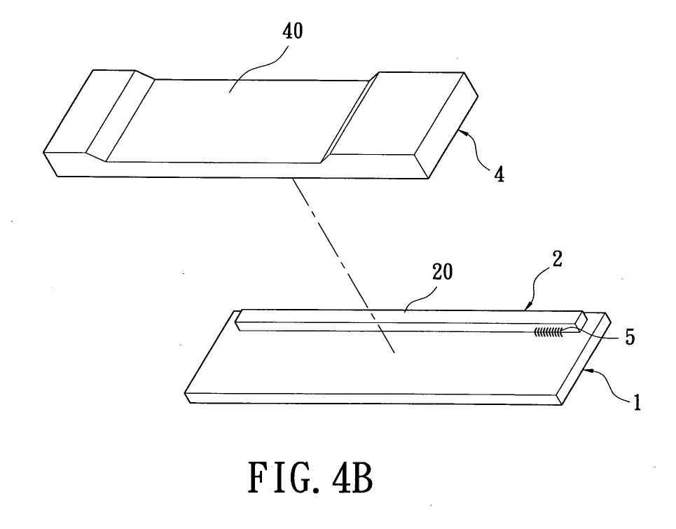

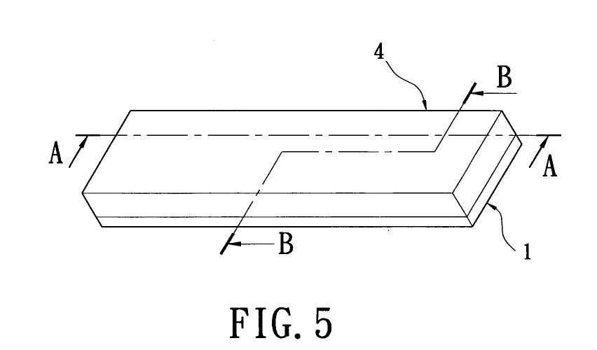

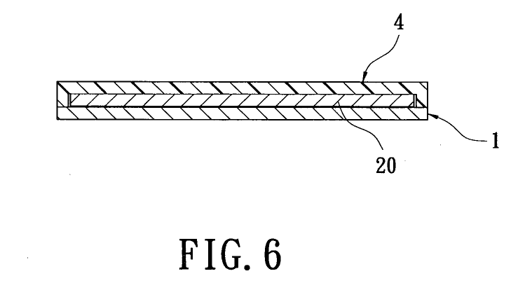

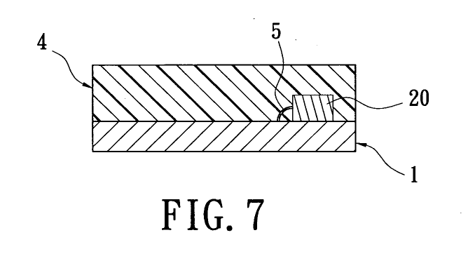

Please refer to FIGS. 4 to 7, illustrating a first embodiment of an optical sensor package of the present invention. The optical sensor package comprises a circuit board 1, an image sensor module 2 and a packaging cap 4.

The image sensor module 2 is mounted on the surface of the circuit board 1 and connected electrically with the circuit board 1. The image sensor module 2 comprises one or more CMOS image sensor chips 20.

The image sensor module 2 is electrically connected to the circuit board 1 via wire-bonding technology. The image sensor module 2 can be electrically connected to the circuit board 1 via SMT technology or another butting technology.

The packaging cap 4 is disposed on the circuit board 1, and integrally packages the image sensor module 2. The packaging cap 4 is transparent and is made of epoxy. The packaging cap 4 can be penetrated by visible light or invisible light, such as infrared/ultraviolet light. Hereby, the optical sensor-package architecture of our invention can be combined with lighting devices or light-emitting modules for scanning and sensing.

Please refer to FIG. 4A, illustrating a second embodiment of an optical sensor package of the present invention. A light-emitting module 3 is disposed on the circuit board 1, and the packaging cap 4 packages the image sensor module 2 and the light-emitting module 3. The light-emitting module 3 comprises a plurality of light-emitting devices 30 and connects electrically to the circuit board 1 via conductive wires 5′. The light-emitting module 3 transmits light through the packaging cap 4, and the image sensor module 2 can receive reflections of the transmitted light via the packaging cap 4.

Hereby, the packaging cap 4 packages the image sensor module 2 integrally. Thus, the architecture of the invention is simple and the manufacturing process of it is easy. Simultaneously, the invention can have electrostatic discharge (ESD) and waterproofing functions, enhance wear-resistance, and reduce the costs of manufacturing and assembling.

Please refer to FIG. 4B, illustrating a third embodiment of an optical sensor package of the present invention. The surface of packaging cap 4 can comprise a concave portion 40. The concave portion 40 has the function of collecting fingerprints.

Furthermore, the concave portion 40 is parallel and close to the CMOS image sensor chip 20, and the CMOS image sensor chip 20 has ESD and waterproofing functions, good wear-resistance, and good sensing sensitivity.

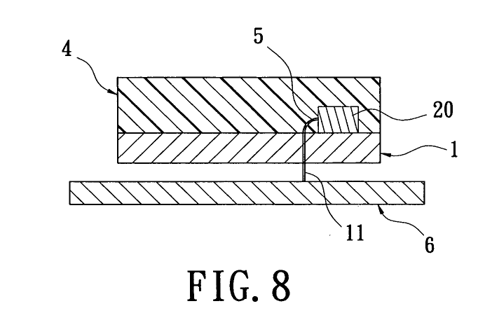

Please refer to FIG. 8, showing a cross-sectional view of the optical sensor package of the present invention connected to another circuit board. A plurality of conductive traces inside circuit board 1 are connected to another circuit board 6 via conductive wires 5; a plurality of open conductive channels 11 are formed at the edge of the circuit board 1, and the conductive traces electrically connect to the circuit board 6 via the open conductive channels 11. Hereby, the image sensor module 2 can electrically connect to another circuit board via the conductive channels.

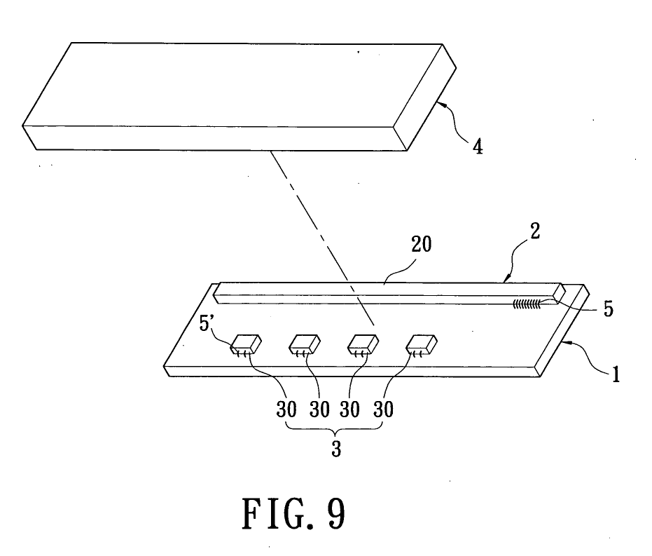

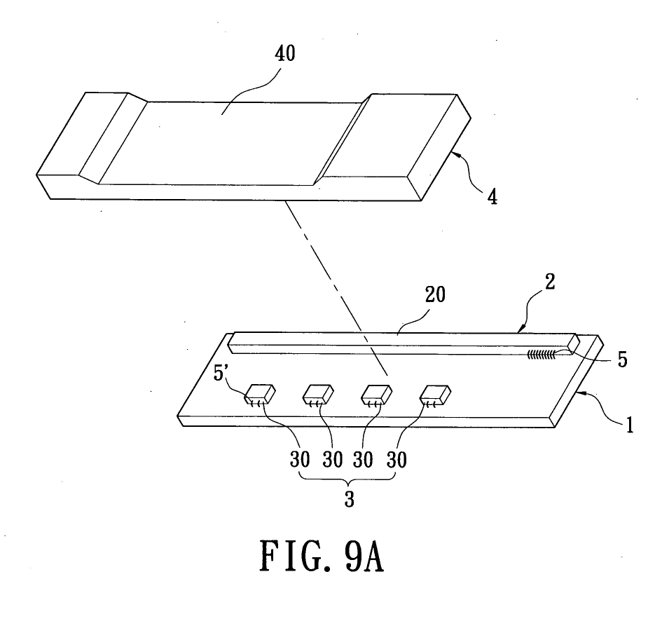

Please refer to FIG. 9, illustrating a forth embodiment of an optical sensor package of the present invention. The optical sensor package comprises a circuit board 1, an image sensor module 2, a light-emitting module 3 and a packaging cap 4.

The image sensor module 2 and the light-emitting module 3 are mounted on the circuit board 1 and are connected electrically with the circuit board 1. The image sensor module 2 comprises a plurality of CMOS image sensor chips 20; the light-emitting module 3 comprises a plurality of light-emitting devices 30.

The image sensor module 2 uses wire-bonding technology to connect electrically to the circuit board 1 via conductive wires 5. The light-emitting module 3 uses wire-bonding technology to connect electrically to circuit board 1 via conductive wires 5′. The image sensor module 2 also can use Surface-Mount-Technology (SMT) to connect electrically to the circuit board 1 via conductive wires 5.

The packaging cap 4 is disposed on the circuit board 1, and the packaging cap 4 integrally packages the image sensor module 2 and the light-emitting module 3. The packaging cap 4 is transparent and is made of epoxy. Because the packaging cap can be penetrated by visible light or invisible light, such as infrared/ultraviolet light. The light-emitting module 3 beams light through the packaging cap 4. The image sensor module 2 receives the reflected light beams through packaging cap 4.

Hereby, the packaging cap 4 packages the image sensor module 2 and the light-emitting module 3 integrally and simultaneously. Thus, the architecture of the invention is simple and the manufacture process of it is easy. Simultaneously, this invention can have ESD and waterproofing functions, enhance wear-resistance, and reduce the costs of manufacturing and assembling.

Please refer to FIG. 9A, illustrating a fifth embodiment of an optical sensor package of the present invention. The surface of packaging cap 4 can comprise a concave portion 40. The concave portion 40 has the function of collecting fingerprints.

The concave portion 40 is parallel and close to the CMOS image sensor chip 20, the CMOS image sensor chip 20 has ESD and waterproofing functions, good wear-resistance, and good sensing sensitivity.

The advantages of the optical sensor package of the invention are illustrated as below:
1. The packaging cap 4 packages the image sensor module 2 and the light-emitting module 3 integrally and simultaneously. Thus, the architecture of the invention is simple and the manufacture process of it is easy.
2. The architecture of the invention can have ESD and waterproofing functions, enhance wear-resistance, and reduce the costs of manufacturing and assembling.
3. The concave portion 40 of the packaging cap 4 has good lighting and sensing performance, so it can raise strike-rate and accuracy-rate for collecting fingerprints.

While the invention has been described in terms of what are presently considered to be the most practical and preferred embodiments, it is to be understood that the invention is not limited to the disclosed embodiments. On the contrary, it is intended to cover various modifications and similar arrangements within the spirit and scope of the appended claims, which are to be accorded with the broadest interpretation so as to encompass all such modifications and similar structures.

What is claimed is:

1. An optical sensor package, comprising:
a first circuit board;
an image sensor module mounted on the first circuit board and connecting electrically to the first circuit board; and
a packaging cap mounted on the first circuit board, packaging the image sensor module.

2. The optical sensor package as claimed in claim 1, wherein
the surface of the packaging cap comprises a concave portion.

3. The optical sensor package as claimed in claim 1, wherein
the packaging cap is transparent and is made of epoxy.

4. The optical sensor package as claimed in claim 3, wherein
the packaging cap can be penetrated by visible light or invisible light.

5. The optical sensor package as claimed in claim 1, wherein
the image sensor module comprises at least one CMOS image sensor chip.

6. The optical sensor package as claimed in claim 1, wherein
the image sensor module is electrically connected to the first circuit board via wire-bonding or SMT technology.

7. The optical sensor package as claimed in claim 1, wherein the image sensor module is electrically connected to the first circuit board via a plurality of conducting wires.

8. The optical sensor package as claimed in claim 7, wherein a plurality of conductive traces are formed inside the circuit board, and the conductive traces are electrically connected to a second circuit board via conducting wires.

9. The optical sensor package as claimed in claim 8, wherein the image sensor module is electrically connected to the second circuit board via the conductive traces.

10. The optical sensor package as claimed in claim 1, wherein
a plurality of conductive channels are formed on the side edge of the first circuit board, the first circuit board has a plurality of conductive traces which electrically connect to a second circuit board via the conductive channels.

11. The optical sensor package as claimed in claim 1, wherein
a light-emitting module is disposed on the first circuit board and the packaging cap packages the light-emitting module.

12. An optical sensor package, comprising:
a first circuit board;
an image sensor module mounted on the first circuit board, connecting electrically to the first circuit board;
a light-emitting module disposed on the first circuit board; and
a packaging cap mounted on the first circuit board packaging both the image sensor module and the light-emitting module.

13. The optical sensor package as claimed in claim 12, wherein
the surface of the packaging cap comprises a concave portion.

14. The optical sensor package as claimed in claim 12, wherein
the packaging cap is transparent and is made of epoxy.

15. The optical sensor package as claimed in claim 14, wherein
the packaging cap can be penetrated by visible light or invisible light.

16. The optical sensor package as claimed in claim 12, wherein
the light-emitting module comprises at least one light-emitting device.

17. The optical sensor package as claimed in claim 12, wherein
a plurality of conductive channels are formed on the side of the circuit board, and the circuit board has a plurality of conductive traces, which are electrically connected to a second circuit board via the conductive channels.

18. The optical sensor package as claimed in claim 12, wherein the image sensor module electrically connects to the second circuit board via the conductive traces.
